(19) United States
(12) Patent Application Publication
(10) Pub. No.: US 2013/0009679 A1
(43) Pub. Date: Jan. 10, 2013

(54) BANG-BANG PHASE DETECTOR WITH HYSTERESIS

(75) Inventors: Vladimir Sindalovsky, Perkasie, PA (US); Lane A. Smith, Easton, PA (US); Jung Cho, Allentown, PA (US)

(73) Assignee: LSI Corporation

(21) Appl. No.: 13/178,812

(22) Filed: Jul. 8, 2011

(51) Int. Cl. H03L 7/06

(52) U.S. Cl. 327/147

(57) ABSTRACT

In described embodiments, a clock alignment system with a digital bang-bang phase detector (BBPD) employs digitally implemented hysteresis. A first BBPD is employed for a phase control loop that compares the phases from two different clock domain sources, where one clock domain source is used as a reference clock for the phase control loop. A second BBPD with delayed reference clock is employed to resolve ambiguous phase relations seen by the first BBPD. An initial state of a BBPD vector, defined as a vector of current values of the first BBPD and the second BBPD, is examined. Based on the initial and subsequent states of the BBPD vector, the non-reference clock is permitted to naturally move to a lock state through action of the phase control loop, or forced to have its phase rotate clockwise or counterclockwise to reach the lock state.

### BACKGROUND OF THE INVENTION

1. Field of the Invention

The present invention relates to communication transceiver clock generator circuits, and, in particular, to phase alignment of differing clock sources using a bang-bang phase detector.

2. Description of the Related Art

In many data communication applications generating several different source clock signals having a known phase alignment is desired. For example, Serializer and De-serializer (SerDes) devices that facilitate the transmission between two points of parallel data across a serial link often must generate multiple clock signals to support various standards. Bang-bang Phase Detectors (BBPD) might be employed in applications that require detection and phase alignment of these different clock domain sources. An exemplary application for such phase control loop employing the BBPD is shown in FIG. 1.

Phase control loop 100 compares the phases from two different clock domain sources, shown as clock 1 (CLK1) generator 101 and clock 2 (CLK2) generator 102, using BBPD 103, where the two different clock source domains operate with the same clock frequency. The result of the phase comparison from BBPD 103 is applied to accumulator 105 to provide for digital filtering that ensures loop stability. The output of accumulator 105 is employed as phase control for one of the clock domains shown as phase control applied to CLK2 generator 102 in FIG. 1. The phase adjustment of phase control loop 100 is performed continuously, resulting in phase alignment of the CLK1 and CLK2 clock source domains. After the CLK1 and CLK2 clock source domains are aligned, data can be transferred from one clock domain to another directly without use of FIFO. Using a FIFO increases latency experienced by data as it passes through the data path. Many standards require low data path latency, and a vendor with the lowest latency gets a significant marketing advantage.

A continuously running phase control loop generates phase jitter due to a limit cycle in this closed loop. In order to reduce jitter generation, gain control 104 is usually employed to adjust gain of accumulator 105 from a relatively high value at the beginning of phase acquisition to a relatively low value after phase alignment of the CLK1 and CLK2 clock source domains (or, “phase lock”) is achieved. This gain control gear shifting might be time based. However, gain control gear shifting is more often based on BBPD 103 and/or accumulator 105 activity switching gears when BBPD 103 flips its output value for the first time (indicating that the phase relation changed from negative to positive or vice versa), which means that the phase difference is close to zero.

FIG. 2 shows a typical digital implementation for BBPD 103 of FIG. 1. The clock, CLK1, from CLK1 generator 101 is employed for this example as a reference clock input to first flip-flop 201 with CLK2 from CLK2 generator 102 applied to an inverting data input of flip-flop 201. Flip-flop 201 registers an inverted state of CLK2 at a positive edge of CLK1, which indicates phase relation between two clock signals through subsequent action of registering the previous inverted state into flip-flop 202 (note that this output signal of flip-flop 202 operates at half the reference clock cycle). A drawback of using a digital BBPD for control over gear shifting steps and as a source of determining the phase relation between two clock signals is the case of the two clock signals being about 180 out-of-phase. For this 180 degrees out-of-phase case, the phase control loop might move to an unstable equilibrium state and might produce erroneous patterns for the output of the BBPD. One cause for erroneous patterns is from different sources of additive noise in the control loop. These noise sources can be classified as: i) deterministic noise in CLK1 and CLK2 clock domain sources; ii) random noise, for example, from a power supply; and iii) control loop limit cycle noise.

FIG. 3 illustrates effects of deterministic noise at half clock frequency in the CLK2 clock source domain with respect to CLK1 for the BBPD of FIG. 1. In the case of deterministic noise at half frequency BBPD will sample a logic “0” during an even period sampling and a logic “1” during an odd period sampling. The BBPD switches at half clock rate when initial phase relation is close to 180 degrees, causing a premature gear shifting to the lower loop gain values applied by the gain control, thereby increasing the time required to achieve phase lock between the two clocks. If the other sources of noise are perfectly symmetric, the loop never moves from 180 degrees out-of-phase case, becoming an equilibrium state. Obviously, when two clock sources align in an 180 degrees out-of-phase equilibrium state, the digital BBPD might produce unexpected and harmful results to circuit operation of the device employing the BBPD.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

In one embodiment, the present invention allows for aligning clock phases of two or more clock sources by a phase control loop, wherein one clock source is a reference clock source. A first bang-bang phase detector (BBPD) generates a first vector component of a BBPD vector for a selected clock source based on the reference clock source. A second BBPD generates a second vector component of the BBPD vector for the selected clock source based on a delayed version of the reference clock source, wherein the first and second vector components indicate a relative phase difference between the selected clock source and the reference clock source. A forcing module, based on the BBPD vector, selectively set its output to either the first vector component or a predefined value. The phase control loop aligns the two or more clock sources with the reference clock source based on the forcing module output.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows an exemplary application for a bang-bang phase detector (BBPD) phase control loop of prior art systems;

FIG. 2 shows a typical implementation for the BBPD of FIG. 1;

FIG. 3 illustrates effects of deterministic noise at half clock frequency in the selected non-reference clock with respect to the reference clock for the BBPD of FIG. 1;

FIG. 4 shows a block diagram of an exemplary clock alignment system having a BBPD with hysteresis operating in accordance with embodiments of the present invention;

FIG. 5 illustrates a timing relationship between the reference clock and a delayed version of the reference clock with respect to the selected non-reference signal;

FIG. 6 illustrates phase relations of the selected non-reference clock with respect to the reference clock in polar coordinates in connection with a BBPD vector;

FIG. 7A illustrates operation of the BBPD with hysteresis when the initial state of a BBPD vector is “01”;

FIG. 7B illustrates operation of the BBPD with hysteresis when the initial state of a BBPD vector is “00”;

FIG. 7C illustrates operation of the BBPD with hysteresis when the initial state of a BBPD vector is “11”;

FIG. 7D illustrates operation of the BBPD with hysteresis when the initial state of BBPD vector indicates the lock state; and

FIG. 8 shows an exemplary Verilog RTL for the BBPD with hysteresis.

### DETAILED DESCRIPTION

In accordance with embodiments of the present invention, a clock alignment system with a digital bang-bang phase detector (BBPD) employs digitally implemented hysteresis. A first BBPD is employed for a phase control loop that compares the phases of signals from at least two different clock domain sources, where one clock domain source is used as a reference clock for the phase control loop. A second BBPD with delayed reference clock is employed to resolve ambiguous phase relations seen by the first BBPD between the reference clock and a selected non-reference clock. An initial state of a BBPD vector, defined as a vector of current values of the first BBPD and the second BBPD, is examined. Based on the initial and subsequent states of the BBPD vector, the selected non-reference clock is permitted to naturally move to a lock state through action of the phase control loop, or otherwise is forced to have its phase rotate clockwise or counterclockwise to reach the lock state.

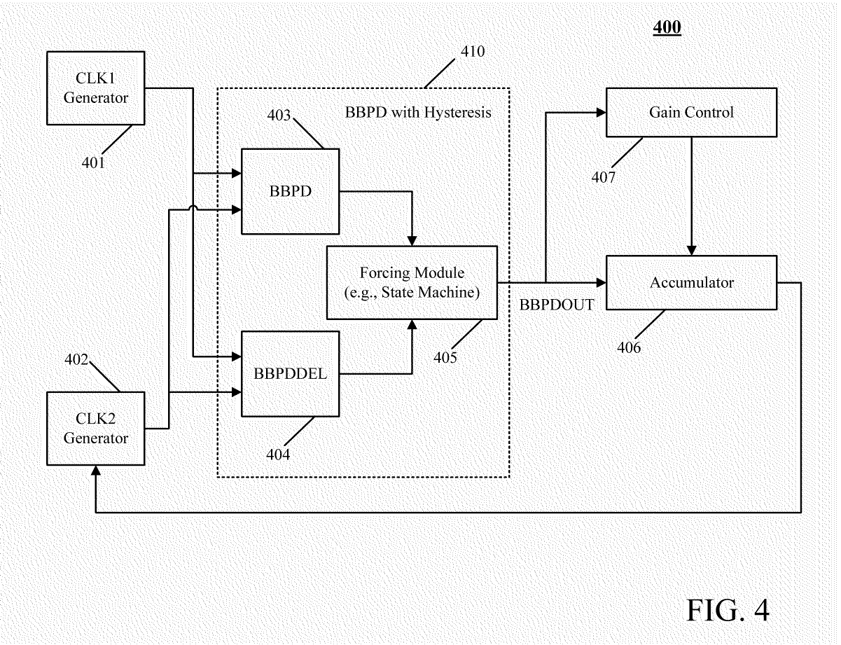

FIG. 4 shows a block diagram of an exemplary BBPD clock alignment system operating in accordance with embodiments of the present invention. Phase control loop 400 comprises clock 1 (CLK1) generator 401, clock 2 (CLK2) generator 402, BBPD with hysteresis 410, accumulator 406, and gain control 407. BBPD with Hysteresis 410 comprises BBPD 403, BBPDDEL 404, and forcing module 405.

Phase control loop 400 compares the phases of clock signals from two different clock domain sources, shown as signals from CLK1 generator 401 and CLK2 generator 402, where the two different clock source domains operate with approximately the same clock frequency. A phase comparison between a reference clock signal (e.g., CLK1 in the exemplary embodiment) and a selected clock signal (e.g., CLK2) is generated using BBPD 403 to provide a BBPD phase comparison value. A phase comparison between a delayed version of the reference clock signal and the selected clock signal is generated using BBPDDEL 404 to provide a delayed BBPD phase comparison value. The result of the phase comparisons from BBPD 403 and from BBPDDEL 404 are applied to forcing module 405, which might be implemented as a simple state machine in logic for some exemplary implementations or with a processor is more sophisticated devices.

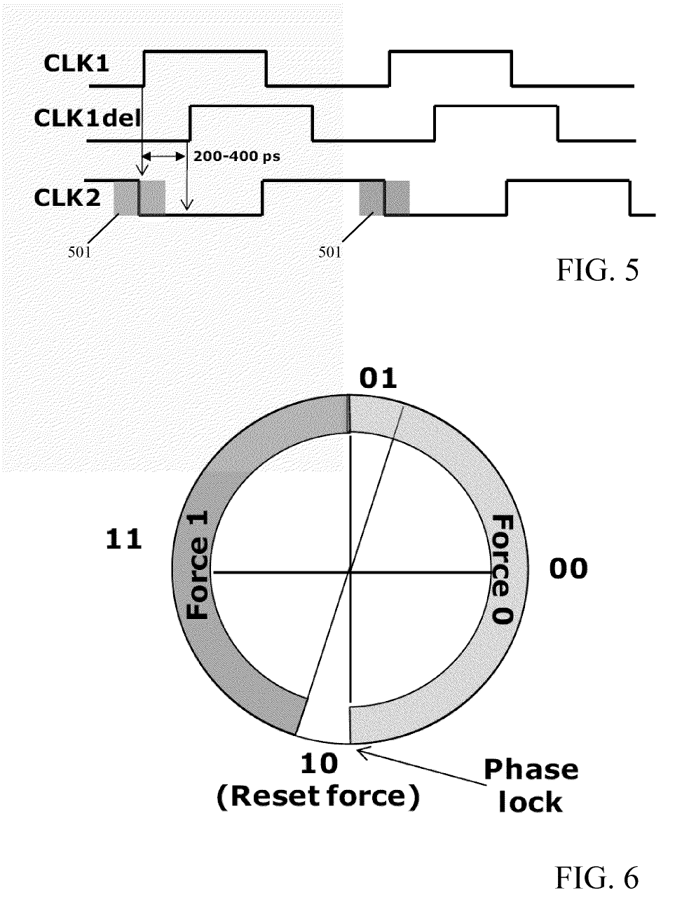

Forcing module 405 forms a BBPD vector from the output value of BBPD 403 and from the output value of BBPDDEL 404. As described subsequently with respect to FIGS. 5 through 8, forcing module 405, based on the BBPD vector, determines whether the two clock sources are relatively near 180 degrees out-of-phase. If the two clock sources are relatively in phase, the phase control loop operates relatively normally, using the output of BBPD 403 as BBPDOUT to naturally move the phase of the selected non-reference clock to align with that of the reference clock (a phase lock state) through action of the phase control loop as described with respect to FIG. 1. If the two clock sources are relatively near 180 degrees out-of-phase, forcing module 405, based on the BBPD vector, selectively sets the value of BBPDOUT to a predefined value that either causes the selected non-reference clock to have its phase rotate clockwise or counterclockwise to reach phase lock with the reference clock.

The value of BBPDOUT is applied to accumulator 406 to provide for digital filtering that ensures loop stability. The output of accumulator 406 is employed as phase control for one of the clock domains, shown as phase control applied to CLK2 generator 402. The phase adjustment of phase control loop 400 is performed continuously, resulting in phase alignment of the CLK1 and CLK2 clock source domains. After the CLK1 and CLK2 clock source domains are aligned, data can be transferred from one clock domain to another directly without use of FIFO. To reduce jitter generation, gain control 407 is employed to adjust gain of accumulator 406 from a relatively high value at the beginning of phase acquisition to a relatively low value after phase alignment of the CLK1 and CLK2 clock source domains is achieved.

Operation of forcing module 405 is now described with respect to timing diagrams shown in FIGS. 5, 6, and 7A-7D. FIG. 5 illustrates a timing relationship between CLK1 and a delayed version of the reference clock CLK1del with respect to the selected non-reference signal CLK2. As shown, the delay as approximately 200-400 psec for the example, which is sufficient to cover noise and jitter region 501 at the transition of CLK2. CLK1 and CLK2 are shown 180 degrees out-of-phase.

The second BBPD (e.g., BBPDDEL 404) uses the delayed version of the reference clock (e.g., delayed CLK1, shown as CLK1de1 in FIG. 5) as a sampling clock for the selected non-reference signal (e.g., CLK2). The amount of delay is desirably selected as a high enough value to overcome possible noise, but a relatively low value when it is compared to half a period of the selected non-reference clock CLK2. Precision for the selected amount of delay is not necessarily critical since the delay is generally used only during the initial phase of achieving phase lock, and is ignored after the two clocks are close to 0 degrees phase relation. BBPDDEL 404 allows for a digitally driven hysteresis in the phase control loop to reduce or otherwise eliminate ambiguity at 180 degrees out-of-phase relation.

FIG. 6 illustrates phase relations of CLK2 in respect to CLK1 in polar coordinates in connection with a BBPD vector: {BBPD, BBPDDEL} formed by, for example, forcing module 405, where BBPD is the bit value of the output of BBPD 403 and BBPDDEL is the bit value of the output of BBPDDEL 404. When the phase relation of CLK2 in respect to CLK1 is close to 180 degrees out-of-phase, this vector might be equal to “11”, “01” or “00” due to different sources of noise in the system. The output state of BBPD with hysteresis 410 depends on the first value of the BBPD vector after the control loop starts from reset (or initial) state.

If the first value of the BBPD vector is “11” then the output (e.g., BBPDOUT) of BBPD with hysteresis 410 is forced to “1” causing CLK2 phase movement counterclockwise. Any changes of the BBPD vector to “01” or “00” are ignored until the vector reaches “10” state. The latter state will be reached when the phase relations between the two clocks approaches 0 degrees. After registering the BBPD vector “10”, BBPD with hysteresis 410 ceases the force to “1” and returns to regular BBPD operation (only using output of, e.g., BBPD 403) in the phase control loop.

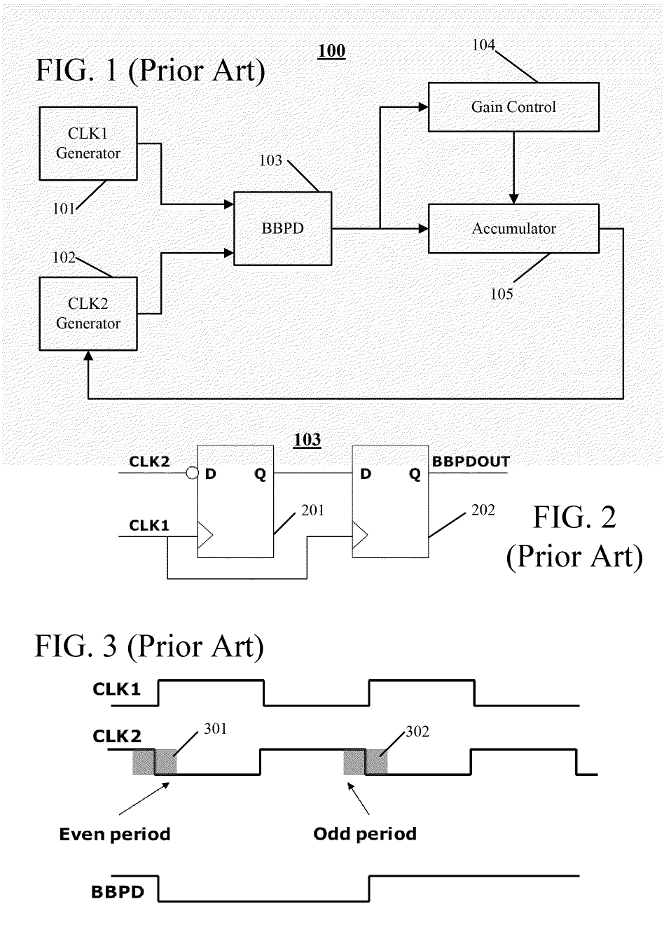

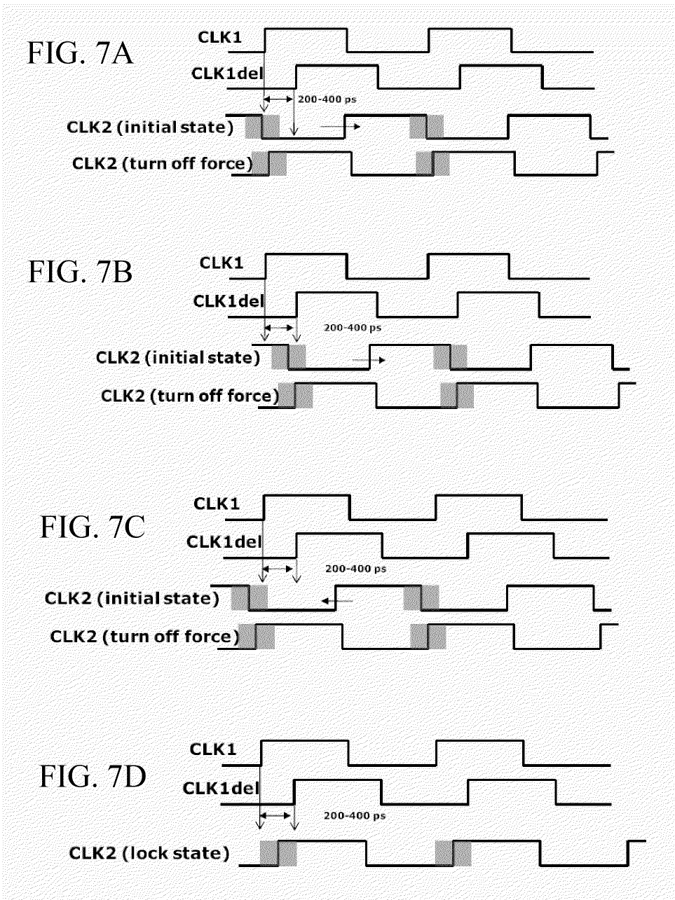

If the first vector after exiting initial state is “01”, then the output of BBPD with hysteresis 410 is forced to “0” causing CLK2 phase movement clockwise. Force to “0” is maintained during the BBPD vector state of “00” until “10” state is reached. The latter state will be reached when the phase relations between the two clocks approaches 0 degree. After registering “10” state BBPD with hysteresis cancels forced to “0” output and starts acting as regular BBPD (see FIG. 2). If the first vector after exiting initial state is “00”, the BBPD vector in this case will transition to “10” without force since the output BBPDOUT is naturally “0”. These different timing scenarios are also illustrated in the time domain in FIGS. 7A-7D.

FIG. 7A shows the initial state of BBPD vector being “01”. In this case the output of BBPD with hysteresis 410 is forced to “0” and CLK2 starts moving right until the BBPD vector becomes “10”. When the BBPD vector becomes “10”, the force to “0” ceases. Meanwhile, the BBPD vector states of “11” or “00” are ignored.

FIG. 7B shows the case of initial vector state “00”. In this case the output of BBPD with hysteresis 410 is set to “0” without force, which causes CLK2 movement to right until the vector becomes equal to “10”. If during this time the BBPD vector gets into “01” state then force to “0” for the output is invoked, and then cancelled when the BBPD vector becomes “10”.

FIG. 7C shows the case of initial vector being equal to “11”. In this case the output of BBPD with hysteresis 410 is forced to “1”, causing CLK2 movement to the left until the BBPD vector becomes “10”, at which time the force to “1” ceases.

FIG. 7D shows the lock state. In this case the BBPDDEL output is not used, and the output of BBPD phase detector is solely based upon CLK2 samples taken on the rising edge of CLK2.

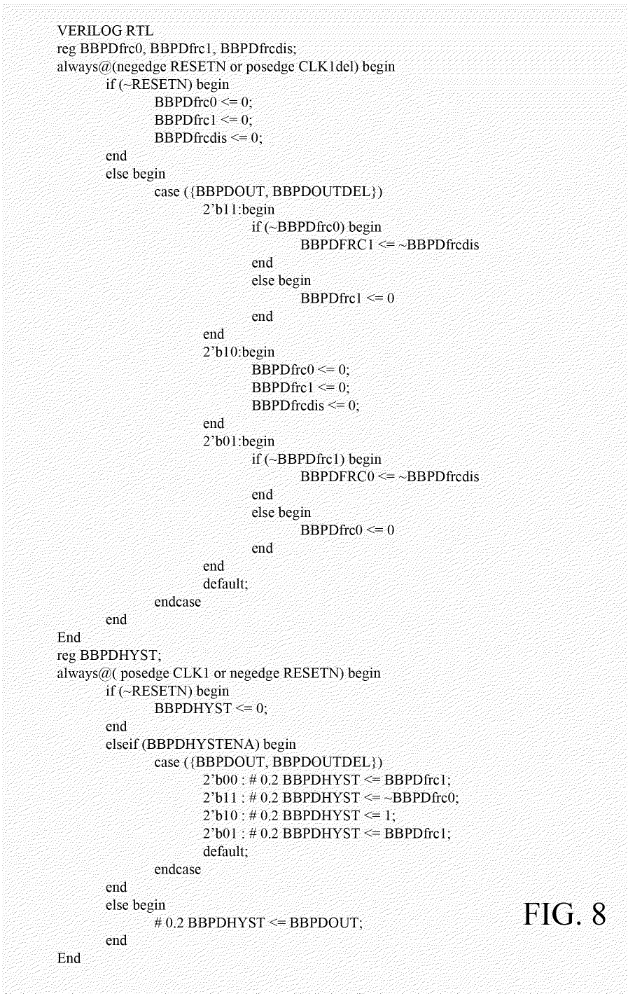

The example Verilog RTL for the proposed BBPD with hysteresis is shown in FIG. 8. RESETN is an active low reset which is released synchronously in respect to CLK1 on power up or on enabling of the clock control loop. BBPDHYSTENA is active high enable signal for the BBPD with hysteresis. If this signal is set low then BBPD performs as a legacy BBPD without hysteresis. BBPDfrcO and PPPDfrc1 are force to “0” and force to “1” states respectively. BBPDfrcdis is the signal which is set low on power up or on any subsequent enable of the clock phase control loop. It allows BBPD to act with hysteresis until the lock state is achieved. After that it is set high in order to prevent BBPD output forcing in the lock state. BBPDHYST is the output of BBPD with hysteresis.

A transceiver operating in accordance with one or more embodiments of the present invention might provide for the following advantages. A bang-bang phase detector with hysteresis reduces or eliminates ambiguity of a detector's output at 180 degrees out-of-phase clock relations, allowing use of the BBPD output to correctly predict proximity to the lock point. Knowledge of the phase relation of the two clocks allows the phase control loop to use the output of the BBPD without potentially moving to an unstable state of operation in the presence of noise. Consequently, such transceiver might exhibit increased reliability in unfavorable communication environments.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Moreover, the terms “system,” “component,” “module,” “interface,”, “model” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Although the subject matter described herein may be described in the context of illustrative implementations to process one or more computing application features/operations for a computing application having user-interactive components the subject matter is not limited to these particular embodiments. Rather, the techniques described herein can be applied to any suitable type of user-interactive component execution management methods, systems, platforms, and/or apparatus.

While the exemplary embodiments of the present invention have been described with respect to processes of circuits, including possible implementation as a single integrated circuit, a multi-chip module, a single card, or a multi-card circuit pack, the present invention is not so limited. As would be apparent to one skilled in the art, various functions of circuit elements may also be implemented as processing blocks in a software program. Such software may be employed in, for example, a digital signal processor, micro-controller, or general purpose computer.

The present invention can be embodied in the form of methods and apparatuses for practicing those methods. The present invention can also be embodied in the form of program code embodied in tangible media, such as magnetic recording media, optical recording media, solid state memory, floppy diskettes, CD-ROMs, hard drives, or any other machine-readable storage medium, wherein, when the program code is loaded into and executed by a machine, such as a computer, the machine becomes an apparatus for practicing the invention. The present invention can also be embodied in the form of program code, for example, whether stored in a storage medium, loaded into and/or executed by a machine, or transmitted over some transmission medium or carrier, such as over electrical wiring or cabling, through fiber optics, or via electromagnetic radiation, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits. The present invention can also be embodied in the form of a bitstream or other sequence of signal values electrically or optically transmitted through a medium, stored magnetic-field variations in a magnetic recording medium, etc., generated using a method and/or an apparatus of the present invention.

Unless explicitly stated otherwise, each numerical value and range should be interpreted as being approximate as if the word “about” or “approximately” preceded the value of the value or range.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements. Signals and corresponding nodes or ports may be referred to by the same name and are interchangeable for purposes here.

It will be further understood that various changes in the details, materials, and arrangements of the parts which have been described and illustrated in order to explain the nature of this invention may be made by those skilled in the art without departing from the scope of the invention as expressed in the following claims.

We claim:

1. Apparatus for aligning clock phases of two or more clock sources by a phase control loop, wherein one clock source is a reference clock source, the apparatus comprising:
a first bang-bang phase detector (BBPD) configured to generate a first vector component of a BBPD vector for a selected clock source based on the reference clock source;
a second BBPD configured to generate a second vector component of the BBPD vector for the selected clock source based on a delayed version of the reference clock source, wherein the first and second vector components indicate a relative phase difference between the selected clock source and the reference clock source; and
a forcing module configured to, based on the BBPD vector, selectively set its output to either the first vector component or a predefined value, wherein the phase control loop aligns the two or more clock sources with the reference clock source based on the forcing module output.

2. The apparatus of claim 1, wherein the BBPD vector indicates whether i) the selected clock source and the reference clock source are relatively closely aligned, ii) the reference clock leads the selected clock source, or iii) whether the reference clock lags the selected clock source.

3. The apparatus of claim 2, wherein the forcing module sets its output to the first vector component when the selected clock source and the reference clock source are relatively closely aligned.

4. The apparatus of claim 2, wherein the forcing module sets its output to the predefined value so as to cause the phase control loop to advance or retard the frequency of the selected clock source when the selected clock source and the reference clock source are substantially 180 degrees out of alignment.

5. The apparatus of claim 1, wherein the phase control loop aligns the two or more clock sources with the output of the first BBPD over a series of cycles of the reference clock, the forcing module configured to, based on each BBPD vector of each clock cycle, selectively set the output of the forcing module to either the first vector component or a predefined value.

6. The apparatus of claim 1, wherein the phase control loop further comprises an accumulator configured to filter noise of the output from the forcing module.

7. The apparatus of claim 6, wherein the phase control loop further comprises a gain control module, the gain control module configured to adjust gain of the accumulator from a relatively high value before aligning the two or more clock sources to a relatively low value after aligning the two or more clock sources, thereby reducing jitter generation.

8. The apparatus of claim 1, wherein the forcing module is embodied in a state machine.

9. The apparatus of claim 1, wherein the apparatus is embodied in a phase control loop circuit of a Serial DeSerializer (SerDes) device.

10. A method of aligning clock phases of two or more clock sources by a phase control loop, wherein one clock source is a reference clock source, the method comprising:
generating, with a first bang-bang phase detector (BBPD), a first vector component of a BBPD vector for a selected clock source based on the reference clock source;
delaying the reference clock source;
generating, with a second BBPD, a second vector component of the BBPD vector for the selected clock source based on a delayed version of the reference clock source, wherein the first and second vector components indicate a relative phase difference between the selected clock source and the reference clock source; and
selectively setting, with a forcing module, an output of the forcing module to either the first vector component or a predefined value; and
aligning, by the phase control loop, the two or more clock sources with the reference clock source based on the output of the forcing module.

11. The method of claim 10, wherein the BBPD vector indicates whether i) the selected clock source and the reference clock source are relatively closely aligned, ii) the reference clock leads the selected clock source, or iii) whether the reference clock lags the selected clock source.

12. The method of claim 11, comprising setting the forcing module output to the first vector component when the selected clock source and the reference clock source are relatively closely aligned.

13. The method of claim 11, comprising:
setting the forcing module output to the predefined value; and
advancing or retarding the frequency of the selected clock source by the phase control loop based on the forcing module output when the selected clock source and the reference clock source are substantially 180 degrees out of alignment.

14. The method of claim 10, comprising:
aligning, by the phase control loop, the two or more clock sources with the output of the forcing module over a series of cycles of the reference clock; and
selectively setting, based on each BBPD vector of each clock cycle, the output of the forcing module to either the first vector component or a predefined value.

15. The method of claim 10, wherein the phase control loop further comprises an accumulator, the method further comprising filtering noise of the output from the forcing module with the accumulator.

16. The method of claim 15, wherein the phase control loop further comprises a gain control module, the method further comprising adjusting, by the gain control module, gain of the accumulator (i) from a relatively high value before aligning the two or more clock sources (ii) to a relatively low value after aligning the two or more clock sources, thereby reducing jitter generation.

17. The method of claim 10, wherein operation of the forcing module is embodied as steps performed by a state machine.

18. The method of claim II, wherein the method is embodied as processing steps in a digital phase control loop of a Serial DeSerializer (SerDes) device.

19. A non-transitory, machine-readable storage medium, having encoded thereon program code, wherein, when the program code is executed by a machine, the machine implements a method for aligning clock phases of two or more clock sources by a phase control loop, wherein one clock source is a reference clock source, comprising the steps of:
generating, with a first bang-bang phase detector (BBPD), a first vector component of a BBPD vector for a selected clock source based on the reference clock source;
delaying the reference clock source;
generating, with a second BBPD, a second vector component of the BBPD vector for the selected clock source based on a delayed version of the reference clock source, wherein the first and second vector components indicate a relative phase difference between the selected clock source and the reference clock source; and
selectively setting, with a forcing module, an output of the forcing module to either the first vector component or a predefined value; and
aligning, by the phase control loop, the two or more clock sources with the reference clock source based on the output of the forcing module.

20. The non-transitory, machine-readable storage medium of claim 19, wherein the BBPD vector indicates whether i) the selected clock source and the reference clock source are relatively closely aligned, ii) the reference clock leads the selected clock source, or iii) whether the reference clock lags the selected clock source.
